(19) United States
(12) Patent Application Publication
(10) Pub. No.: US 2025/0102590 A1
(43) Pub. Date: Mar. 27, 2025

(54) BATTERY MANAGEMENT DEVICE AND BATTERY MANAGEMENT PROGRAM

(71) Applicant: HITACHI, LTD., Tokyo (JP)

(72) Inventors: Jun TSUNODA, Tokyo (JP); Yutaka UEDA, Tokyo (JP); Hiroya FUJIMOTO, Tokyo (JP); Eri ISOZAKI, Tokyo (JP); Toru KOUNO, Tokyo (JP); Ryo WAKABAYASHI, Tokyo (JP)

(21) Appl. No.: 18/730,341

(22) PCT Filed: Oct. 14, 2022
(86) PCT No.: PCT/JP2022/038368

§ 371 Date: Jul. 19, 2024

(30) Foreign Application Priority Data
Feb. 17, 2022 (JP) 2022-022986

(51) Int. Cl. G01R 31/392; G01R 31/3842; H01M 10/42; H01M 10/48

(52) U.S. Cl. CPC G01R 31/392; G01R 31/3842; H01M 10/425; H01M 10/482; H01M 10/486; H01M 2010/4271

(57) ABSTRACT

An object of the invention is to provide a technique capable of accurately evaluating soundness of a battery without excessively depending on a degree of progress of deterioration. A battery management device according to the invention evaluates the soundness of the battery using a first voltage change amount in a first period starting from a start time point before an inflection point of a voltage curve after completion of charging and a second voltage change amount in a second period starting from a start time point before an inflection point of a voltage curve after completion of discharging (see FIG. 5).

### TECHNICAL FIELD

The present invention relates to a technique for managing a state of a battery.

### BACKGROUND ART

A technique for accurately grasping a deterioration state of a secondary battery in a short time is important for a power accumulation system, an automatic electric vehicle, and another system to safely and optimally use the secondary battery. In addition, this technique makes maintenance of the secondary battery remarkably efficient.

Specific examples of a method for detecting deterioration of a secondary battery include the following PTLs 1 and 2. In PTL 1, a deterioration state is detected using a thermal simulation model. In PTL 2, under a state of charge (SOC) of a specific storage battery, a voltage change (open circuit voltage (OCV)) in a state where energization is stopped is acquired, and a battery state is determined based on a sum or a difference of absolute values thereof.

### CITATION LIST

### Patent Literature

PTL 1: WO2021/023346

PTL 2: JP2016-176709A

SUMMARY OF INVENTION

### Technical Problem

A deterioration evaluation using a simulation as described in PTL 1 is accurate for deterioration detection of a battery over time and grasp of a deterioration tendency. However, this is an evaluation under a specific condition. Accordingly, it is difficult to detect a battery that causes sudden deterioration and a failure.

The deterioration detection using the OCV described in PTL 2 is accurate under conditions such as a specific state of charge and temperature. However, in an actual operation, there are constraints on a long time energization stop (10 minutes) and a measurement environment. Accordingly, it is considered that the technique described in the same PTL only evaluates soundness of the battery. In addition, the soundness evaluation by the OCV is accurate for a battery in which the deterioration largely progresses. However, there is a possibility that the accuracy decreases for a battery of which the degree of deterioration is low, such as initial deterioration or aged deterioration.

The invention has been made in view of the above problems, and an object thereof is to provide a technique capable of accurately evaluating soundness of a battery without excessively depending on a degree of progress of deterioration.

### Solution to Problem

A battery management device according to the invention evaluates soundness of a battery using a first voltage change amount in a first period starting from a start time point before an inflection point of a voltage curve after completion of charging and a second voltage change amount in a second period starting from a start time point before an inflection point of a voltage curve after completion of discharging.

### ADVANTAGEOUS EFFECTS OF INVENTION

According to a battery management device of the invention, it is possible to accurately evaluate soundness of a battery without excessively depending on a degree of progress of deterioration. Other problems, configurations, advantages, and the like of the invention will become apparent from the following description of embodiments.

### BRIEF DESCRIPTION OF DRAWINGS

FIG. 1 shows a discharge current amount (Ah) of a battery under a predetermined acceleration test condition.

FIG. 2 is a diagram showing voltage changes in a state of charge and a state of discharge of each of a sound battery and a deteriorated battery.

FIG. 3 is a diagram showing changes with time in an output voltage of the battery during a pause period after a charging operation and a pause period after a discharging operation of the battery.

FIG. 4 is a configuration diagram of a battery system according to Embodiment 1.

FIG. 5 is a distribution diagram in which a voltage change after discharging (ΔVdis) and a voltage change after charging (ΔVcha) are plotted for each battery.

FIG. 6 is an example of data for deriving a difference (ΔVdis-ΔVcha) and a ratio (ΔVcha/ΔVdis) from values of ΔVdis and ΔVcha of the battery.

FIG. 7 is a distribution diagram in which the batteries are divided according to a period until a failure.

FIG. 8 is a distribution diagram for predicting a period from an operation period of the battery to a future failure.

FIG. 9A shows an example of a GUI presented by a calculation unit.

FIG. 9B shows another example of the GUI presented by the calculation unit.

FIG. 9C shows another example of the GUI presented by the calculation unit.

FIG. 10 is a diagram showing an operation of a battery management device according to Embodiment 1.

FIG. 11 is a diagram showing a configuration for setting a reference value for each battery type.

FIG. 12 shows a result obtained by selecting the reference value for each battery.

FIG. 13 is an example of data showing a calculation result obtained by applying a SoC correction equation to ΔVdis and ΔVcha.

FIG. 14 shows a change in ΔVdis and ΔVcha plots when a SoC is corrected.

FIG. 15 is a flowchart showing an operation of a battery management device according to Embodiment 3.

FIG. 16 is an example of data showing a calculation result when a temperature correction equation is applied to ΔVdis and ΔVcha.

FIG. 17 shows a change in ΔVdis and ΔVcha plots when a battery temperature is corrected.

FIG. 18 is a flowchart showing an operation of a battery management device according to Embodiment 4.

FIG. 19 is an example of data showing a calculation result when a voltage correction equation is applied to ΔVdis and ΔVcha.

FIG. 20 shows a change in ΔVdis and ΔVcha plots when a battery voltage is corrected.

FIG. 21 is a flowchart showing an operation of a battery management device according to Embodiment 5.

FIG. 22 is a schematic diagram showing an operation form of a battery management device according to Embodiment 6.

FIG. 23 is a diagram showing a configuration example of the battery management device according to Embodiment 6.

FIG. 24 shows an operation form of a battery management device according to Embodiment 7.

### DESCRIPTION OF EMBODIMENTS

### Embodiment 1

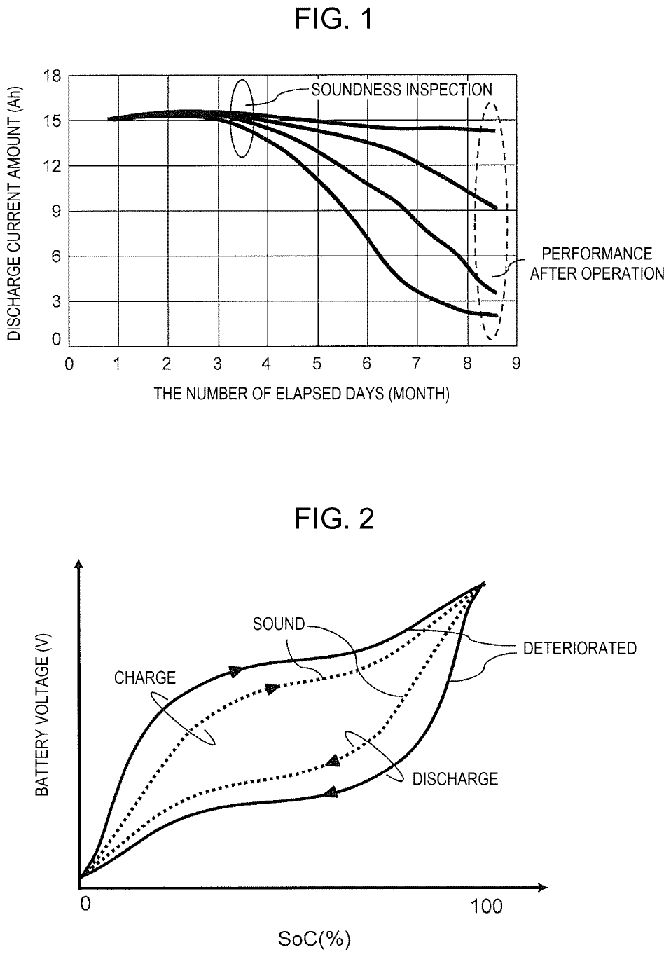

FIG. 1 shows a discharge current amount (Ah) of a battery under a predetermined acceleration test condition. In FIG. 1, a horizontal axis represents the number of elapsed days from the start of operation of the battery, and a vertical axis represents the discharge current amount (Ah). In general, a dischargeable current amount (herein, referred to as the discharge current amount (Ah)) of the battery tends to decrease depending on aged deterioration. In addition, the deterioration of the battery is different depending on a use time and an operation method, and a battery in which the deterioration has progressed has a characteristic that the discharge current amount (Ah) decreases as compared with a sound battery.

As shown in FIG. 1, even after operating the same period, deterioration in performance is different depending on the individual difference of the battery. In Embodiment 1, soundness is inspected at a timing surrounded by a solid line as an example. In the soundness inspection, a battery which is sound and a battery in which deterioration progresses are relatively distinguished based on values of the discharge current amount (Ah) of the batteries. Since deterioration states are relatively determined, it is not desirable to perform an evaluation in the number of elapsed days in which the change in the discharge current amount (Ah) is small. Accordingly, the soundness inspection of the battery is to be performed in any number of elapsed days in which the discharge current amount (Ah) sufficiently changes.

A region surrounded by a dotted line in FIG. 1 indicates the performance of the battery after operation. When the soundness is inspected in the solid line of FIG. 1, all batteries show the same discharge current amount (Ah). However, it can be seen that there is a battery in which the performance is greatly reduced due to an operation. Accordingly, if the soundness can be inspected in any number of elapsed days and a sign of a battery whose performance is reduced can be grasped in an early stage, the battery can be replaced before the battery is largely deteriorated. In addition, one battery is selected at a time when the decrease in the discharge current amount (Ah) is small, and is collated with a result of at least one of acceleration test data, operation result data in a market, and AI-based training data, whereby deterioration prediction of the battery is also possible. In FIG. 1, the soundness inspection is performed at one time point, but may be performed a plurality of times.

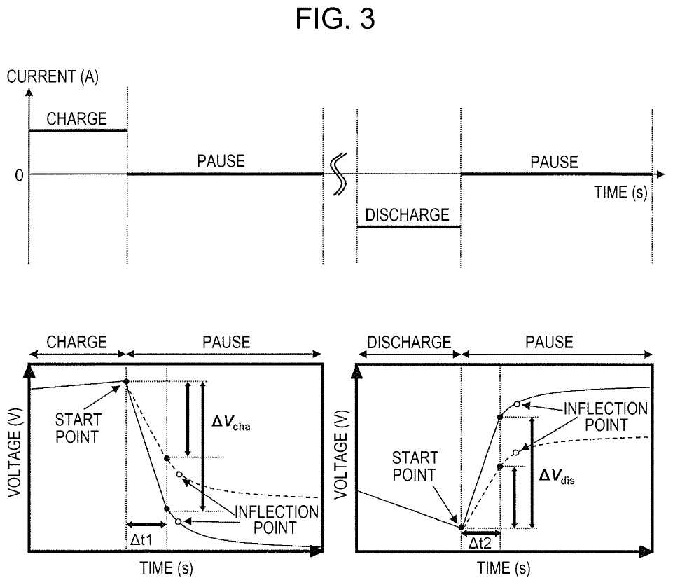

FIG. 2 is a diagram showing voltage changes in a state of charge and a state of discharge of each of a sound battery and a deteriorated battery. In FIG. 2, the horizontal axis represents an SOC, and the vertical axis represents a battery voltage. FIG. 2 shows that the battery voltage changes during charging and discharging in the same SoC due to a difference in the deterioration of the battery. FIG. 2 further shows that the voltage change (here, referred to as hysteresis) during charging and discharging becomes larger as the deterioration of the battery progresses. From a relationship between the SOC and the battery voltage shown in FIG. 2, the deterioration of the battery can be detected by evaluating hysteresis of at least one of charging and discharging. In the invention, the SOC of the battery can be relatively determined by acquiring a current charge amount from, for example, a battery management unit (BMU) and comparing the current charge amount with a charge amount at the time of full charge.

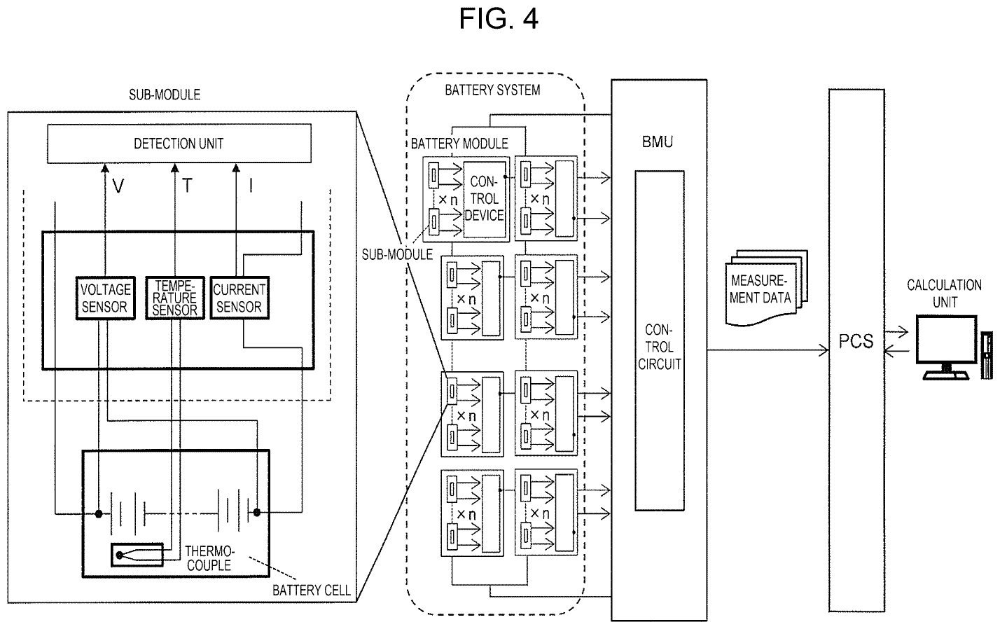

FIG. 3 is a diagram showing changes with time in an output voltage of the battery during a pause period after a charging operation and a pause period after a discharging operation of the battery. The upper part of FIG. 3 shows current waveforms at the time of transition from the charging operation to the pause period and at the time of transition from the discharging operation to the pause period. In the upper part of FIG. 3, the horizontal axis represents a time, and the vertical axis represents a battery output current. Charging and charging commands are performed according to a current command, and when the current is positive (>0), charging is performed, when the current is negative (<0), discharging is performed, and when the current is O, a pause period is performed.

The lower left part of FIG. 3 shows a change with time in the battery voltage during the charging operation and the subsequent pause period. The lower right part of FIG. 3 shows a change with time in the battery voltage during the discharging operation and the subsequent pause period. In both the lower left part of FIG. 3 and the lower right part of FIG. 3, the horizontal axis represents a time and the vertical axis represents a battery voltage. For a voltage waveform, the dotted line indicates a voltage waveform of the sound battery acquired at an operation initial stage, and the solid line indicates a voltage waveform of the battery, in which the deterioration progresses, due to a long-term operation or the individual difference of the battery. An inflection point is a point immediately before the voltage during the pause period has a saturation tendency.

For the voltage change after charging (ΔVcha) and the voltage change after discharging (ΔVdis), a period, between a completion time point at which the charging of the battery is completed or a start time point after the completion time point and before an inflection point of a voltage curve for time and a first time point at which a first time has elapsed from the start time point, is defined as a first period. A time length of the first period is expressed as Δt1. A period, between a completion time point at which the discharging of the battery is completed or a start time point after the completion time point and before an inflection point of a voltage curve for time and a second time point at which a second time has elapsed from the start time point, is defined as a second period. A time length of the second time is expressed as Δt2. A change amount of the voltage during the first period is defined as ΔVcha, and a change amount of the voltage during the second period is defined as ΔVdis. ΔVcha and ΔVdis can be used to evaluate the soundness of the battery as described later.ΔAVcha and ΔAVdis most remarkably appear in a period in which the output voltage suddenly changes immediately after the start of the pause period after charging and after discharging. Accordingly, ΔVcha and ΔAVdis are to be acquired at a timing at which a sudden change in the output voltage as shown in FIG. 3 is observed.

Next, a change in accuracy of the values (or absolute values) of ΔVcha and ΔVdis according to acquisition time points of start points and end points of the time lengths Δt1 and Δt2 will be described. When the time lengths Δt1 and Δt2 are acquired immediately after charging and after discharging, and the end points are acquired at the inflection point or on the charging side and the discharging side of the inflection point, since a steep voltage change can be acquired in the pause period, ΔVcha and ΔVdis having large change amounts and high accuracy can be acquired. This is an example, and as long as Δt1 and Δt2 can be acquired with sufficient accuracy, the start point may not necessarily be after charging and immediately after discharging, and may be acquired after any time, in which a steep voltage change can be acquired, has elapsed. For the end point, when the inflection point is acquired beyond a predetermined range, ΔVcha and ΔVdis can be sufficiently acquired although the change amount is slightly reduced. ΔVcha and ΔVdis depend on a characteristic of the battery, and thus an appropriate timing may be defined for each battery type.

The time lengths Δt1 and Δt2 may be set in optimum ranges in accordance with a sampling frequency and a measurement environment. A measurement time (the time lengths of Δt1 and Δt2) is assumed to be acquired in a range of milliseconds to several seconds (for example, about 1 ms to 5 s) in Embodiment 1, but the measurement time may be changed in accordance with a measurement device or a stepping width of voltage acquisition. As shown in the lower left part of FIG. 3 and the lower right part of FIG. 3., ΔVcha and ΔVdis of the battery, in which the deterioration progresses, tend to be larger than those of the sound battery. Accordingly, the voltage waveforms of the sound battery and the deteriorated battery can be relatively compared to determine the deterioration of the battery.

In Embodiment 1, ΔVdis and ΔVcha are measured within a short time range from the completion of charging or discharging. As compared with a case where an OCV is acquired over a period of time of about 10 minutes during charging and discharging as in PTL 2, a time constraint on measurement can be greatly relaxed. Accordingly, Embodiment 1 can be applied to an application, in which it is difficult to detect deterioration due to an OCV, such as a battery device that needs to be constantly operated or electric vehicles having different battery characteristics depending on vehicle types.

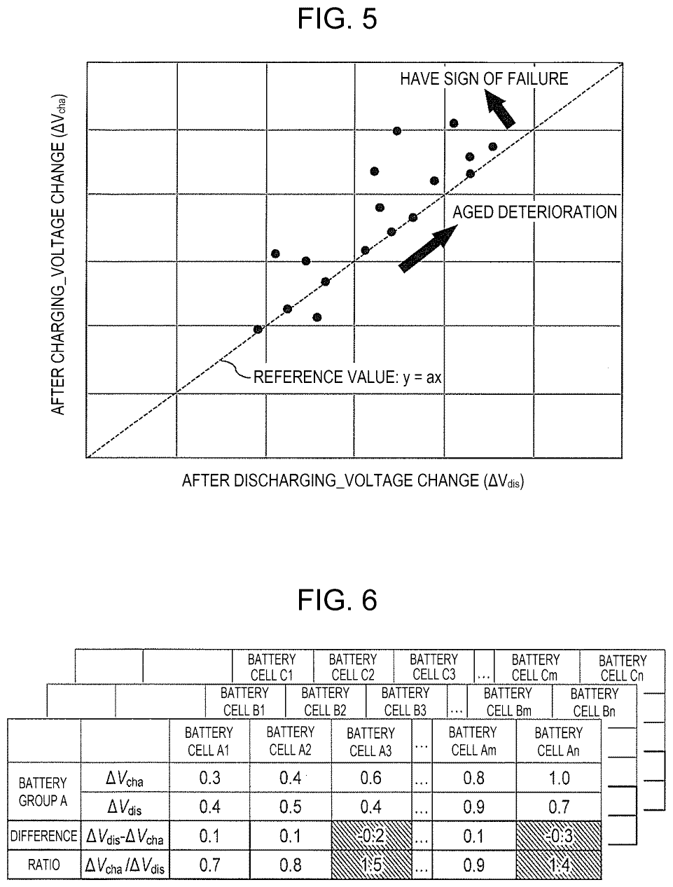

FIG. 4 is a configuration diagram of a battery system according to Embodiment 1. In FIG. 4, the battery system including a battery module including a plurality of sub-modules and a control circuit thereof, a BMU, and a computer (calculation unit) that performs calculation processing can be used as implementation examples of Embodiment 1. For example, the calculation unit can acquire measurement data such as an output voltage, an output current, and a temperature of the battery via the BMU, and use the measurement data to perform a method for evaluating the soundness of the battery according to Embodiment 1.

The battery system includes the BMU and a plurality of battery modules connected in series and in parallel. The battery module includes the plurality of sub-modules connected in series, and the sub-module includes a plurality of battery cells connected in parallel. Each of the battery cells has a thermocouple.

The detection unit detects a current, a temperature, and a voltage output from the battery cell via a current sensor, a temperature sensor, and a voltage sensor, and acquires detection values thereof. A current value acquired by the detection unit is used by the calculation unit to determine the start point, the state of charge, and the state of discharge in FIG. 3. The detection values are acquired by the detection unit, and then transmitted to the calculation unit as measurement data via the BMU. The battery module has an active cell balance controller (control device) for controlling a distribution of charge during charging and discharging.

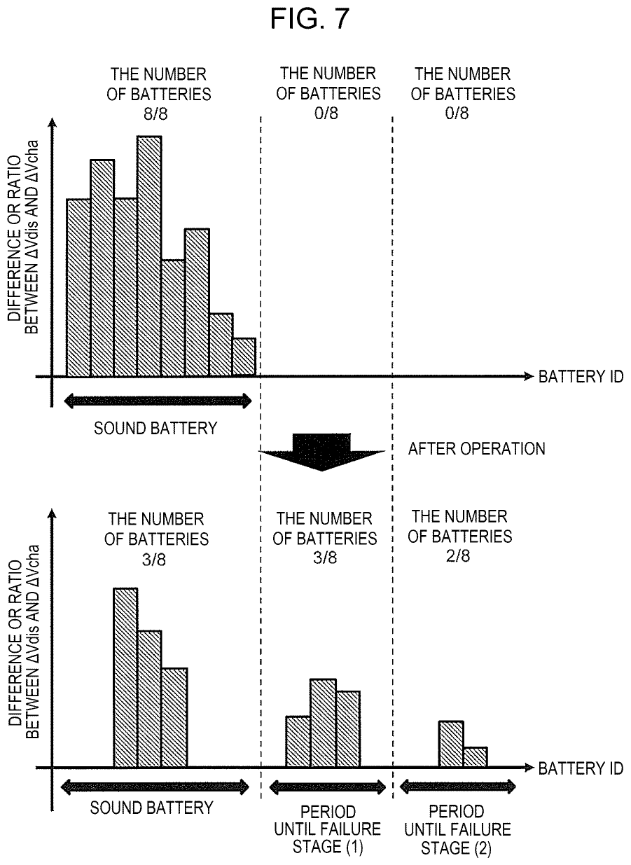

FIG. 5 is a distribution diagram in which the voltage change after discharging (ΔVdis) and the voltage change after charging (ΔVcha) are plotted for each battery. In FIG. 5, the horizontal axis represents the voltage change after discharging (ΔVdis), and the vertical axis represents the voltage change after charging (ΔVcha). FIG. 5 is a two-dimensional plot of the values of ΔVdis and ΔVcha acquired in FIG. 4. By using this plot, it is possible to relatively detect a sign of deterioration or a failure of the battery, and it is possible to grasp the state of the battery having a possibility of a potential failure.

A reference value (y=ax) in FIG. 5 can be used to distinguish between a sound battery and a battery having a sign of a failure. In the sound battery, ideally, a voltage change during charging and a voltage change during discharging are equal to each other. Therefore, the reference value can be, for example, a linear equation y=x. In Embodiment 1, a perpendicular line from the reference value to each plot is relatively evaluated to distinguish between the sound battery and the battery having a sign of a failure. A deterioration state and a failure sign state of the battery are classified into two types: (a) aged deterioration due to an operation method and battery variation; and (b) a state in which the balance of the battery is lost due to an abnormality in an electrode or inside of the battery, and a sign of a failure can be detected. A reference for distinguishing these states will be described below.

(1) A battery is more sound on the reference value and closer to an origin.

The sound battery is usually plotted on the reference value, and a perpendicular distance to the reference value is 0. Accordingly, it is determined that the battery on the reference value is sound. In addition, as the plot is closer to the origin, hysteresis is smaller, and the battery is determined to be sound. A battery plotted on the lower right of the reference value (ΔVdis>ΔVcha) due to a measurement error is also evaluated as a sound battery. The reason why the lower right region is regarded as sound is that, in a case of a sound battery, energy is accumulated in the battery by charging, and thus discharge energy tends to be larger than charge energy. According to the above, when at least ΔVdis>ΔVcha, the battery can be evaluated to be sound.

(2) A battery that is on the reference value but far from the origin is a battery in which aged deterioration progresses.

A plot existing on the reference value but far from the origin indicates that at least one of ΔVdis and ΔVcha is relatively larger than that of other batteries. This indicates that a difference in hysteresis occurs due to an individual difference of the battery. Accordingly, a battery having a relatively large distance from the origin as compared with other batteries can be evaluated as a battery in which aged deterioration has progressed. The distance from the origin is proportional to a degree of progress of the aged deterioration.

(3) A battery deviating from the reference value and having a divergence with the reference value is a battery having a sign of a failure.

The battery close to the failure deviates from the reference value as shown in FIG. 5, and the perpendicular distance from the reference value tends to increase as the number of cycles of the battery until the failure decreases. This indicates that some abnormality occurs in the electrode of the battery or the inside of the battery, and the balance of the hysteresis starts to be lost. Therefore, the number of cycles until the failure is relatively determined by determining a relative length of the perpendicular line from the reference value in any plot. Accordingly, a battery that deviates from the reference value (ΔVdis<ΔVcha) is evaluated as a battery having a sign of a failure.

Next, a method for distinguishing a scale of a period until a failure by relatively evaluating a distance of a perpendicular line drawn from each plot to the reference value among batteries having a sign of a failure will be described. The number of cycles of the battery until the failure is correlated with the perpendicular distance from the reference value, the balance of the hysteresis of the battery is lost as the perpendicular line is longer, and the number of cycles until the failure becomes smaller. The number of cycles also matches the acceleration test data. Accordingly, among batteries approaching to a failure, the battery having a relatively long perpendicular line drawn from the reference value is determined to be a battery having a small number of cycles until the failure, and a “period until a failure: stage (1)” and a “period until a failure: stage (2)” are determined according to the distance. This is determined according to a usable period as a sound battery, and is defined as “the period until the failure: stage (1)<the period until the failure: stage (2)”. In addition, the plot of the aged deterioration changes depending on the battery, and the reference value may have a curvature. In this case, the period until the failure is classified into stages by defining an asymptote having a curvature as a new reference value and relatively evaluating a distance from the reference value to the plot.

As described above, it is possible to predict a failure of a battery by estimating performance reduction of the battery at an early stage using the result of at least one of the acceleration test data, the operation result data in the market, and the AI-based training data, and the length of the perpendicular line, and detecting the battery having a high possibility of a potential failure.

In addition, by acquiring ΔVdis and ΔVcha of the plurality of batteries and relatively evaluating the perpendicular line from the reference value to each plot, it is possible not only to separate sound batteries from deteriorated batteries, but also to detect a battery having aged deterioration and a sign of a failure. In this detection method, the aged deterioration and the sign of the failure may be determined simultaneously, or either the aged deterioration or the sign of the failure may be determined preferentially.

A slope (a) at the reference value (y=ax) in FIG. 5 may be changed according to the type of the battery. By freely setting the slope according to the type of the battery, the determination accuracy of the battery having the sign of the failure can be improved. As an example, the slope a is set to 1.1 (=1+0.1). Accordingly, since a range in which the battery is determined to have a sign of a failure is narrower than that in the case of a=1, it is possible to more strictly determine whether the battery is a battery having a sign of a failure (it is possible to avoid erroneously detecting a battery having a very small sign of a failure). When the slope a is set to 0.9 (=1−0.1), the range in which the battery is determined to have a sign of a failure is wider than that in the case of a=1. Accordingly, since a larger number of batteries are determined to be batteries having a sign of a failure, it is possible to grasp not only batteries in the “period until the failure: stage (1)” and the “period until the failure: stage (2)” but also batteries having a possibility of a potential failure.

By changing an intercept of the reference value (y=ax), it is possible to obtain the same effect as when the slope is changed. As an example, when the intercept is set to 0.2, the range in which the battery is determined to have a sign of a failure is narrowed as in a case where the slope is increased, and thus it is more strictly evaluated whether the battery is a battery having a sign of a failure. When the intercept is set to −0.2, the range in which the battery is determined to have a sign of a failure is widened, it is possible to grasp a battery having a possibility of a potential failure.

As described above, by changing the slope and the intercept of the reference value, it is possible to detect and determine a battery having a sign of a failure, which is optimum for the operation of the battery system. The changes of the slope and the intercept can also be used for correction when an error occurs in a measurement device.

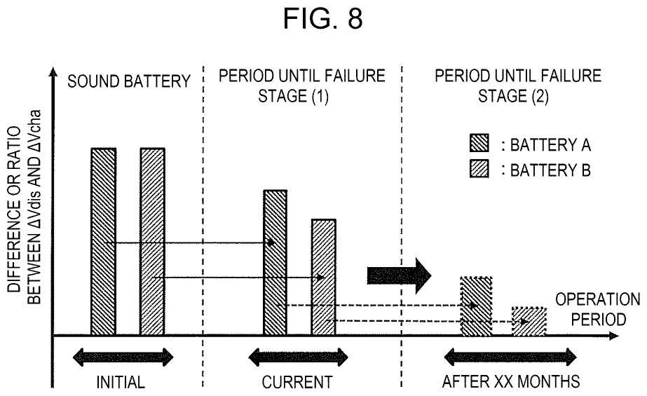

FIG. 6 is an example of data for deriving a difference (ΔVdis−ΔVcha) and a ratio (ΔVcha/ΔVdis) from values of ΔVdis and ΔVcha of a battery. Whether a battery has aged deterioration or a sign of a failure may be determined by using not only a two-dimensional mapping shown in FIG. 5 but also at least one of the difference (ΔVdis−ΔVcha) and a ratio (ΔVcha/ΔVdis).

FIG. 6 shows ΔVdis and ΔAVcha of battery cells Al to An constituting a battery group A and battery cells B1 to Bn and C1 to Cn respectively constituting battery groups B and C. Columns of the difference (ΔVdis−ΔVcha) and the ratio (ΔVcha/ΔVdis) in FIG. 6 show calculation results derived based on ΔVdis and ΔVcha of the respective battery cells. FIG. 6 shows that when the difference or the ratio is equal to or more than a predetermined value (or equal to or less than a predetermined value), it can be determined that the battery is a deteriorated battery or a battery having a sign of a failure.

ΔVcha and ΔVdis of a sound battery gradually increase in proportion to a use period (=aged deterioration), and ΔVcha is lower than (or equal to) ΔVdis. Accordingly, the difference (ΔVdis−ΔVcha) is 0 or positive (>0), and the ratio (ΔVcha/ΔVdis) is 1.0 or less. There is no large deviation from these values. However, due to the characteristic of the battery, since more energy is accumulated in ΔVdis than in ΔVcha, and ΔVdis has a larger value, it is determined that the battery is sound even if the ratio is less than 1.0.

On the other hand, for the battery cells A3 and An in FIG. 6, AVcha exceeds the value of ΔVdis (the difference (ΔVdis−ΔVcha) is negative (<0)), or the ratio (ΔVcha/ΔVdis) exceeds 1.0. It can be determined that although the battery is operated only in the same period as that of the sound battery, the balance between ΔVcha and ΔVdis is lost and the battery has a sign of a failure.

There is a battery in which the difference (ΔVdis−ΔVcha) is positive (22 0) and the ratio (ΔVcha/ΔVdis) is also 1.0 or less, but ΔVcha and ΔVdis are larger than that of other batteries. This battery is determined to be a battery in which aged deterioration progresses among the battery group [battery cell Am].

That is, the aged deterioration is proportional to the magnitude of the values of ΔVcha and ΔVdis, and a battery having a sign of a failure can be determined by the positive or negative of the difference (ΔVdis−ΔVcha) or the value of the ratio (ΔVcha/ΔVdis).

The battery cell A1 (ΔVcha: 0.3, ΔVdis: 0.4) is compared with the battery cell Am (ΔVcha: 0.8, ΔVdis: 0.9) in FIG. 6. In both cases, the difference is positive (>0) and the ratio is 1.0 or less, but ΔVcha and ΔVdis are changed in spite of the operation in the same period.

In the method of PTL 2, deterioration is detected by the difference (ΔVdis−ΔVcha) between ΔVcha and ΔVdis. Accordingly, the difference in both the batteries A1 and Am is 0.1,and a difference with a sound battery may not be accurately detected. Therefore, when the soundness cannot be determined based on the difference, the soundness is evaluated using the ratio (ΔVcha/ΔVdis) in Embodiment 1. Accordingly, a ratio of 0.7 is obtained for the battery A1, and a ratio of 0.9 is obtained for the battery Am. Accordingly, it can be determined that aged deterioration of the battery Am has progressed as compared with that of the battery A1. However, since the ratio does not exceed 1.0, it is determined that the battery Am is not in a battery state having a sign of a failure.

As described above, in Embodiment 1, by using the difference or the ratio between ΔVcha and ΔVdis, it is possible to detect not only a largely deteriorated battery and a battery having a sign of a failure but also a battery in an aged deterioration state with high accuracy. Further, since it is possible to quickly detect a sign of a battery having aged deterioration and a sign of a failure, it is possible to predict a failure early.

In Embodiment 1, it is possible to determine a battery having aged deterioration and a sign of a failure regardless of the use order of the difference or the ratio as an evaluation reference. Although decimal values are used for ΔVdis and ΔVcha in the embodiment, evaluation may be performed using other values.

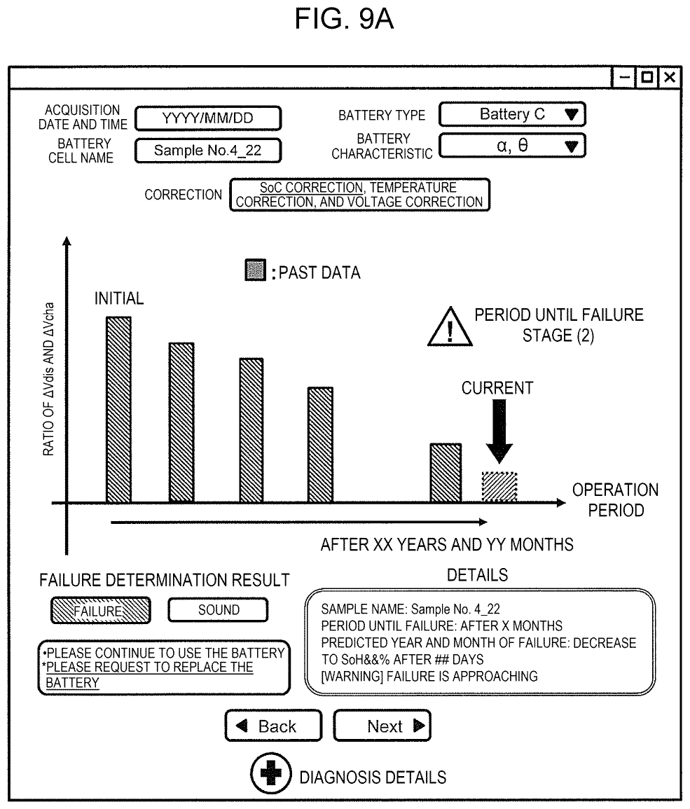

FIG. 7 is a distribution diagram in which the batteries are divided according to a period until a failure. The upper part of FIG. 7 is a distribution diagram before the start of the operation, and the lower part of FIG. 7 is a distribution diagram after the start of the operation. Each diagram shows a relationship between the operation period of the battery and the degree of deterioration or the degree of the sign of the failure. In FIG. 7, the horizontal axis represents a battery ID, and the vertical axis represents the difference or the ratio between ΔVcha and ΔVdis. In order from the left in FIG. 7, the batteries are classified into sound batteries, a period until a failure: stage (1), and a period until a failure: stage (2). The degree of the sign of the failure corresponds to the perpendicular distance between the plot and the reference line described in FIG. 5, and each battery may be classified using the perpendicular distance. The period until the failure: stage (2) may be determined to be a battery having a particularly small number of cycles until a failure. For the period until the failure, the batteries can be classified with higher accuracy by being associated with the result of at least one of the acceleration test data, the operation result data in the market, and the AI-based training data.

By associating the battery ID with the difference (ΔVdis−ΔVcha) or the ratio (ΔVcha/ΔAVdis) between ΔVcha and ΔVdis to form a distribution diagram, it is possible to relatively grasp the number of batteries having a sign of a failure and the period until the failure. When a system storage battery or a large storage battery system is operated, it is possible to place an order for a battery having a short period until a failure several months before or replace a battery having a sign of a failure by providing a threshold of the limit number of batteries having a sign of a failure in advance.

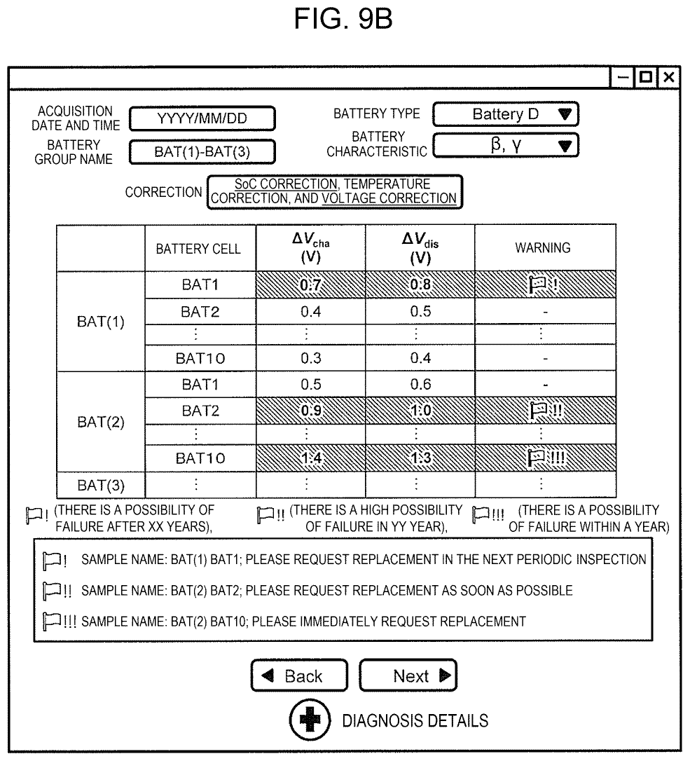

FIG. 8 is a distribution diagram for predicting a period from the operation period of the battery to a future failure. FIG. 8 shows the operation period and a degree of deterioration progress of a specific battery. The horizontal axis represents the operation period, and the vertical axis represents the difference or the ratio between ΔVcha and ΔVdis. Similarly to FIG. 7, a scale of a sign state of a failure of a battery is different depending on a range, and is classified into a sound battery, a period until a failure: stage (1), and a period until a failure: stage (2) from the left. The dark shaded bar graph is a battery A, and a light shaded bar graph is a battery B.

Detection of a battery having a deterioration state or a possibility of a failure by the difference (ΔVdis−ΔVcha) or the ratio (ΔVcha/ΔVdis) using the values of ΔVdis and ΔVcha can be applied temporarily or continuously. When it is desired to determine a current battery state, it is possible to detect aged deterioration of the battery or instantaneously determine the battery having a possibility of a potential failure by acquiring the current ΔVdis and ΔVcha. In a case of continuously detecting a battery having a deterioration state or a possibility of a failure using ΔVdis and ΔVcha, it is possible to evaluate the current battery state using past deterioration detection data information. Accordingly, deterioration transition of the battery can be grasped over time, and the failure of the battery can be estimated. Although the bar graph is used in the embodiment, a line graph may be used. FIG. 8 can also be displayed in a GUI described later.

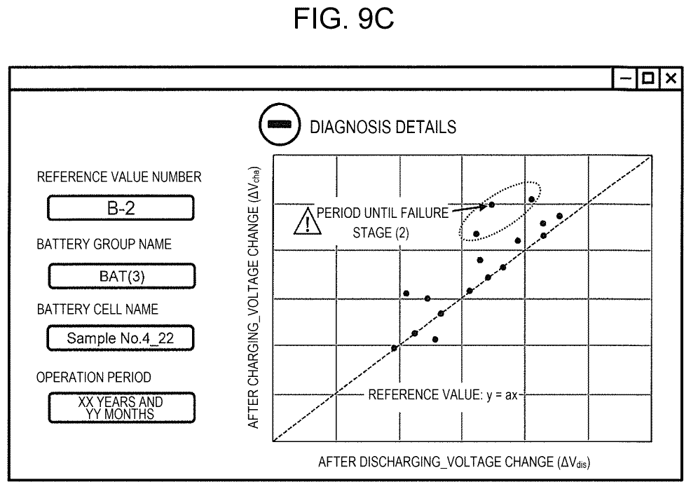

FIG. 9A shows an example of the graphical user interface (GUI) presented by the calculation unit. The calculation unit displays, on the GUI, results of deterioration detection and deterioration prediction of the system. The GUI displays at least one of determination as to whether each battery cell of the battery cells has aged deterioration and a sign of a failure from an operation initial stage to the present, a failure determination result (continuation of use or a replacement request), a warning, a predicted year and month of a future failure, correction display of a reference value, a battery type, a battery characteristic, a battery group, and a battery cell name. A bar graph surrounded by a solid line indicates past battery data, and a bar graph surrounded by a dotted line indicates battery data currently acquired. In the embodiment, the aged deterioration of the battery according to the operation period is evaluated by the ratio of ΔVdis and ΔVcha, and may be evaluated by the difference between ΔVdis and ΔVcha.

FIG. 9B shows another example of the GUI presented by the calculation unit. The GUI of FIG. 9A presents a state of a battery cell, whereas the GUI of FIG. 9B presents states of battery cells constituting a battery group. Shaded battery cells (BAT(1): BAT1, BAT (2): BAT2 and BAT10) indicate battery cells in which ΔVcha and ΔVdis deviate. Warnings are displayed for these battery cells.

FIG. 9C shows another example of the GUI presented by the calculation unit. The calculation unit presents, on the GUI, a determination result as to whether there is a battery having a deterioration state or a sign of a failure using the two-dimensional mapping described in FIG. 5. The GUI displays at least one of a voltage change after charging, a voltage change after discharging, a reference value, a reference value number of a battery, a battery group, a battery cell name, and an operation result. The calculation result is shown inside a dotted line in a table of FIG. 9C.

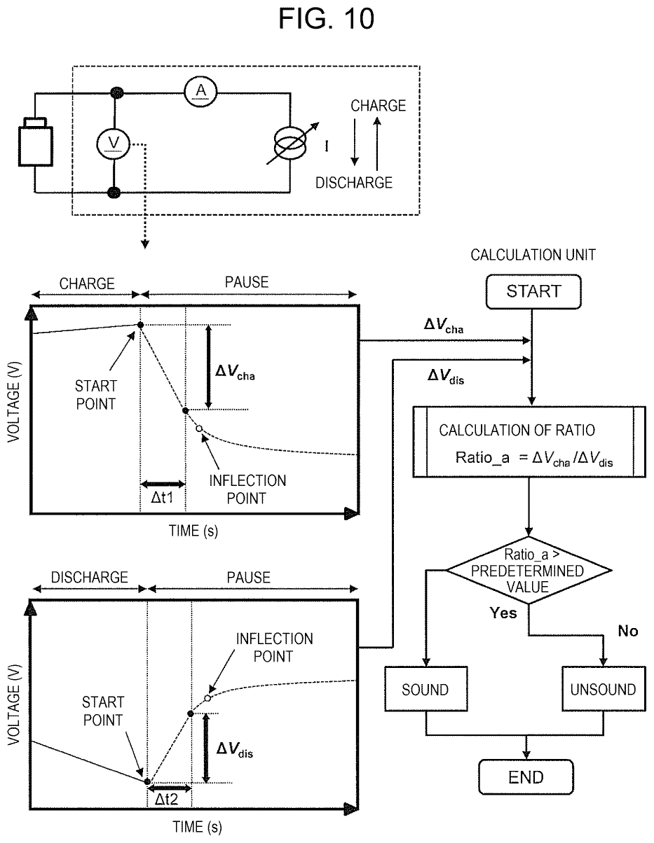

FIG. 10 is a diagram showing an operation of a battery management device according to Embodiment 1. The battery management device includes the detection unit and the calculation unit. The calculation unit acquires ΔVcha and ΔVdis based on a battery voltage acquired by the detection unit, calculates at least one of a difference or a ratio between ΔVcha and ΔVdis (as a ratio in FIG. 10), and compares the result with a threshold to evaluate whether the battery is sound. As for a determination reference of the soundness, the method described in FIGS. 5 and 6 may be used.

The calculation unit may acquire voltages, currents, and temperatures after charging and after discharging from the detection unit before calculating the difference or the ratio, and determine whether the battery is in the pause period after charging or in the pause period after discharging. When the battery is not in the pause period, this flowchart is ended, or waits until the pause period is reached. In the case of the pause period, a subsequent step of calculating the difference or the ratio is performed. Whether the battery is in the pause period may be determined based on whether the battery current after charging changes from a positive direction to 0, and may be determined based on whether the battery current after discharging changes from a negative direction to 0.

### Embodiment 2

In Embodiment 2 of the invention, differences in battery type, battery characteristic, and battery attribute for each battery cell in which a failure is detected are used, and based on these differences, a reference value is determined for each battery type via a reference value determination code. By sorting of a reference value determination equation, it is possible to accurately grasp whether a battery has aged deterioration and a sign of a failure, and thus deterioration detection accuracy is improved. Other configurations are the same as those of Embodiment 1.

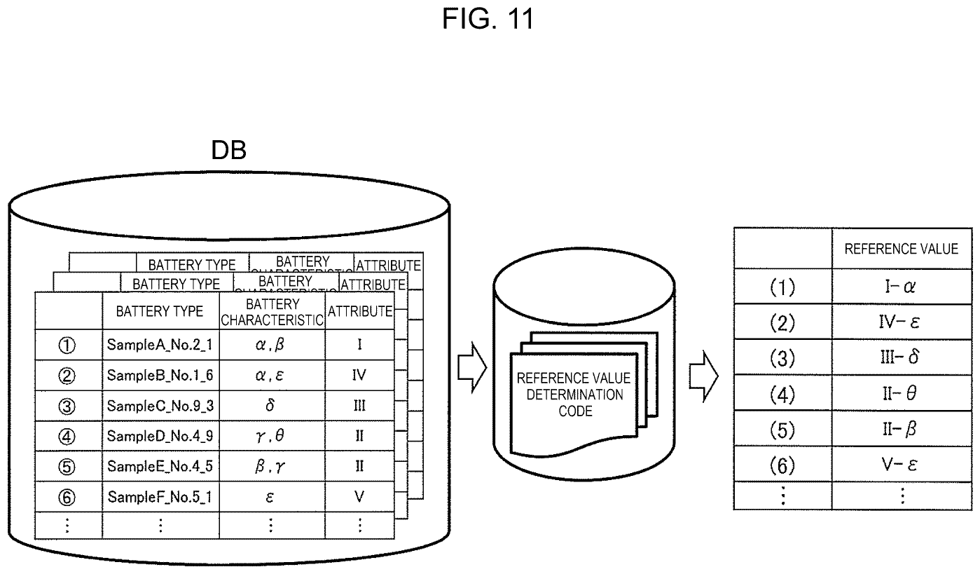

FIG. 11 is a diagram showing a configuration for setting a reference value for each battery type. A storage device (DB) provided in a calculation unit stores battery types (Sample A_No. 2_1, Sample B_No. 1_6, . . . ), battery characteristics ([α, β], [α, ε], [δ], . . . ), and attributes (I, IV, III, . . . ) for each battery, and further stores a reference value (y=ax in Embodiment 1) for each combination thereof. The calculation unit determines a reference value according to the above classifications, and evaluates soundness of a battery using the reference value. FIG. 11 shows an example in which a reference value such as (I- α) or (II-θ) is determined for each combination of a characteristic and an attribute of the battery.

A type or a model number of a secondary battery is classified as the battery type. The battery type may be classified into a battery cell level or a battery group level. The battery characteristic means a classification depending on a constituent element such as an electrode or a solution of the battery, and can be classified even when the battery has a single characteristic or two or more characteristics. The battery attribute means a classification depending on a reaction rate of each battery.

The calculation unit determines the reference value for each battery type via a reference value determination code shown in FIG. 11 based on the above classifications. The reference value determination code is implemented by past deterioration detection data. The calculation unit selects a reference value that best matches the past deterioration detection data for each battery type. For an unknown battery, a reference value of the battery having a characteristic closest to the past deterioration detection data may be used. A type and an attribute of the unknown battery may be newly stored in the reference value determination code as a database.

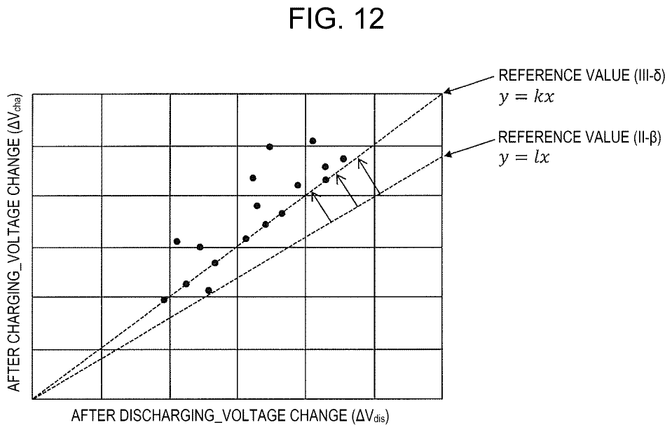

FIG. 12 shows a result obtained by selecting the reference value for each battery. The horizontal axis represents a voltage change after discharging, and the vertical axis represents a voltage change after charging. The reference value (y=ax) used for detecting a battery having aged deterioration and a sign of a failure can be selected for each combination of one or more of a battery type, a battery characteristic, and a battery attribute. In a two-dimensional plot of FIG. 12, a reference value (II-β): y=1x is updated to a reference value (III-δ): y=kx. Based on the reference value after the change, it is understood that a sound battery and a deteriorated battery can be separated with higher accuracy.

Although only the slope is updated in FIG. 12 as an example, the intercept may also be changed in addition to the slope. By selecting the reference value according to the battery type and the like, it is possible not only to classify types of a battery having a deterioration state or a sign of a failure with high accuracy, but also to detect a battery having a possibility of a potential failure.

### Embodiment 3

In Embodiment 3 of the invention, a method for evaluating soundness of a battery regardless of a current SoC value by converting ΔVcha and ΔVdis into values corresponding to any SoC using an SoC correction equation will be described. Other configurations are the same as those of Embodiment 1.

In deterioration detection using the OCV in PTL 2, measurement under the same SOC condition is essential. That is, in order to detect deterioration of a battery in PTL 2, it is necessary to acquire an OCV under a specific SoC which is normal. Therefore, in Embodiment 3, ΔVcha and ΔVdis are acquired without adjusting the SoC to a specific value on a battery cell (or a battery module) side, and the values are converted into values corresponding to any SoC by a correction function. Using the converted ΔVcha and ΔVdis, the soundness of the battery is evaluated in the same manner as in Embodiment 1. Accordingly, the soundness of the battery can be evaluated in any SoC without depending on a specific SoC state.

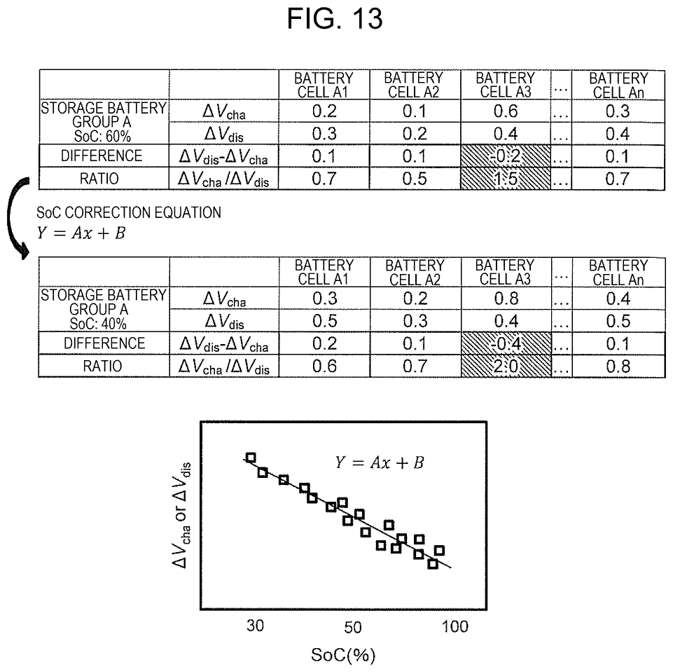

FIG. 13 is an example of data showing a calculation result obtained by applying the SoC correction equation to ΔVdis and ΔVcha. The upper part of FIG. 13 shows measurement results of ΔVdis and ΔVcha after charging and discharging in any SoC (SoC=60% in this example). The middle part of FIG. 13 shows a result of conversion into a value corresponding to SoC=40% by applying the SoC correction equation (Y=Ax+B (Equation 1)) to ΔVdis and ΔVcha in SoC=60% in the upper part of FIG. 13. A conversion equation is an example, and other conversion equations may be used. The same applies to conversion equations in the following embodiments.

The lower part of FIG. 13 shows a method for determining a conversion equation. ΔVcha and ΔVdis under various SoC conditions are acquired in advance, and a conversion equation is obtained by specifying an equation that approximates a relational equation therebetween. For a deteriorated battery, an intercept of the conversion equation changes, but a slope may be regarded as having dependency equivalent to that of the relational equation of Equation 1. The same applies to conversion equations in the following embodiments.

When the upper part and the middle part of FIG. 13 are compared with each other, it can be seen that a battery having a deterioration state or a sign of a failure can be determined even when the conversion equation is applied to ΔVdis and ΔVcha. In addition, a normal battery can be correctly determined. Accordingly, even when ΔVdis and ΔVcha are acquired in any SoC, it can be said that deterioration can be detected and a state of a battery having a possibility of a potential failure can be determined. ΔVdis and ΔVcha before correction do not necessarily have to be acquired in the same SoC, but may be converted into values corresponding to specific SoCs by applying the conversion equation to ΔVdis and ΔVcha acquired in different SoCs. The same applies to conversion equations in the following embodiments.

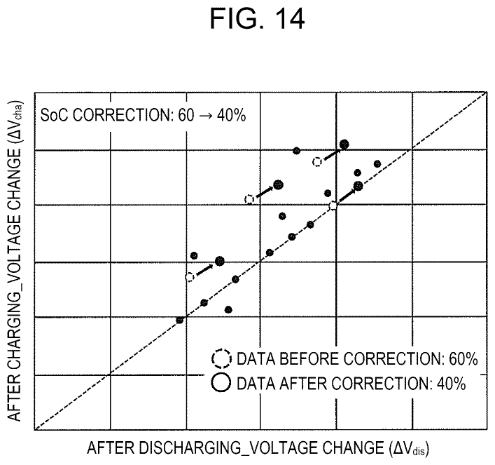

FIG. 14 shows a change in ΔVdis and ΔVcha plots when an SoC is corrected. A dotted line plot in FIG. 14 indicates data before correction (SoC: 60%), and a solid line plot indicates data after correction (SoC: 40%). The horizontal axis represents a voltage change after discharging, and the vertical axis represents a voltage change after charging. The data after correction can be applied to either a sound battery or a deteriorated battery. Determination of a battery having a sign of a failure in a plot after correction is the same as that before the correction. By acquiring at least one of a difference and a ratio, it is possible to accurately detect a battery having a deterioration state or a sign of a failure.

In Embodiment 3, a degree of freedom of a measurement environment (SoC) is added in addition to instantaneous measurement of ΔVdis and ΔVcha. This solves a problem of an environmental constraint (SoC) in which SoCs are to be unified, in addition to a time constraint in which an OCV is acquired over about 10 minutes during charging and discharging in PTL 2.

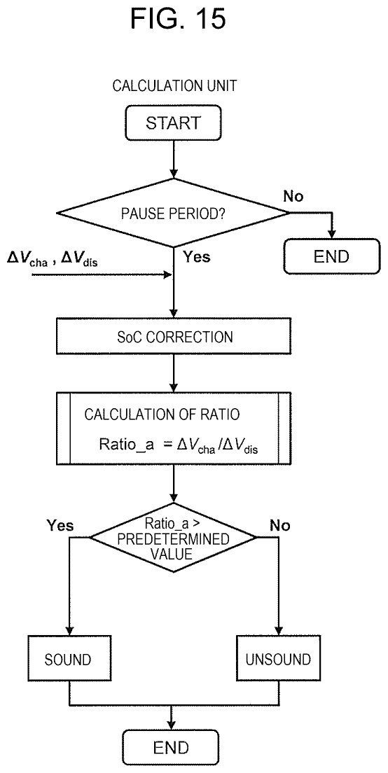

FIG. 15 is a flowchart showing an operation of a battery management device according to Embodiment 3. In Embodiment 3, before calculating the difference or ratio between ΔVdis and ΔVcha, a calculation unit applies the conversion equation to the difference or the ratio. However, when the current SoC is the same SoC as when a reference value used for performing determination of soundness is obtained, the conversion equation is not necessary. Other steps are the same as those in Embodiment 1.

### Embodiment 4

In Embodiment 4 of the invention, a method for evaluating soundness of a battery regardless of a current battery temperature by converting ΔVcha andΔinto values corresponding to any battery temperature using a battery temperature correction equation will be described. Other configurations are the same as those in Embodiment 1.

In the deterioration detection using the OCV in PTL 2, ΔVcha and ΔVdis need to be measured at the same temperature. That is, in order to evaluate the soundness of the battery in PTL 2, it is necessary to measure ΔVcha and ΔVdis at a specific battery temperature. Therefore, in Embodiment 4, ΔVcha and ΔVdis are acquired without adjusting the battery temperature on a battery cell (or a battery module) side, and values thereof are converted into values corresponding to any battery temperature by a correction function. Using the converted ΔVcha and ΔVdis, the soundness of the battery is evaluated in the same manner as in Embodiment 1. Accordingly, the soundness of the battery can be evaluated at any battery temperature without depending on a specific battery temperature.

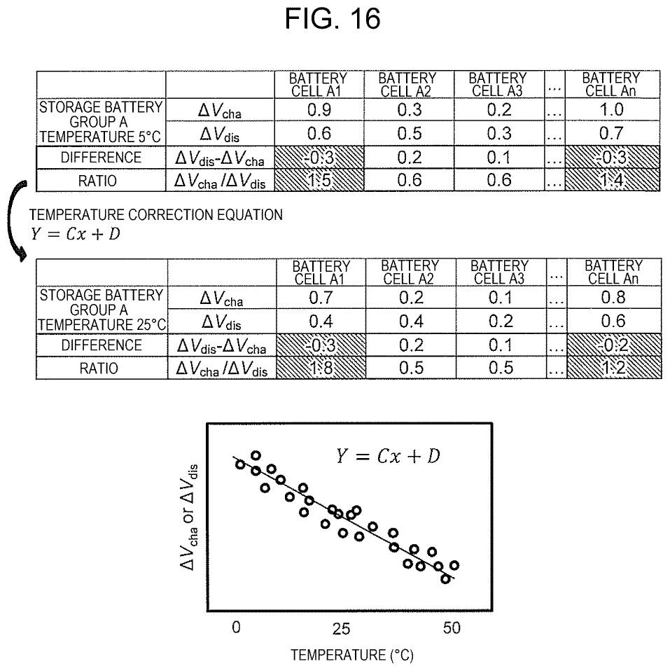

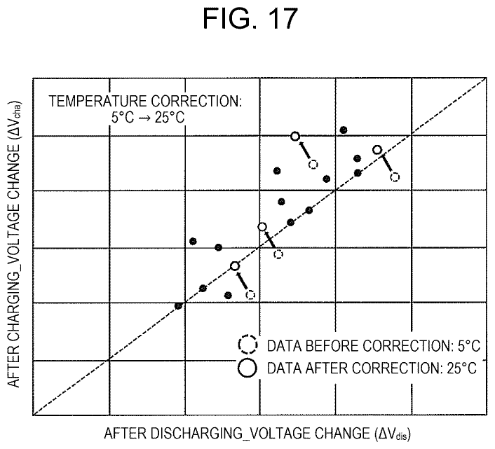

FIG. 16 is an example of data showing a calculation result when the temperature correction equation is applied to ΔVdis and ΔVcha. The upper part of FIG. 16 shows measurement results of ΔVdis and ΔVcha after charging and discharging at any battery temperature (5° C. in the upper part of FIG. 16). The middle part of FIG. 17 shows a result of conversion into a value corresponding to a battery temperature=25° C. by applying a temperature correction equation (Y=Cx+D (Equation 2)) to ΔVdis and ΔVcha at the temperature of 5° C. in the upper part of FIG. 16.

The lower part of FIG. 16 shows a method for determining a conversion equation. ΔVdis and ΔVcha are acquired under various battery temperature conditions, and a conversion equation is obtained by specifying an equation that approximates a relational equation therebetween.

When the upper part and the middle part of FIG. 16 are compared with each other, it can be seen that a battery having a deterioration state or a sign of a failure can be determined even when battery temperature correction is applied to ΔVdis and ΔVcha. In addition, a normal battery can be correctly determined, Accordingly, even when ΔVdis and ΔVcha are acquired under different battery temperature conditions, it can be said that deterioration can be detected and a battery state having a possibility of a potential failure can be determined.

FIG. 17 shows a change in ΔVdis and ΔVcha plots when the battery temperature is corrected. A dotted line plot in FIG. 17 indicates data before correction (temperature: 5° C.), and a solid line plot indicates data after correction (temperature: 25° C.). The horizontal axis and the vertical axis are the same as those in Embodiment 3. The data after correction can be applied to any of a sound battery, a battery in a deterioration state, and a battery having a sign of a failure. In addition, the determination of the battery having the sign of the failure in the plot after the correction is the same as that before the correction. By acquiring at least one of a difference and a ratio, it is possible to accurately detect a battery having a deterioration state or a sign of a failure.

In Embodiment 4, a degree of freedom of a measurement environment (temperature) is added in addition to instantaneous measurement of ΔVdis and ΔVcha. This solves a problem of an environmental constraint (temperature) in which the temperatures under the measurement environment are to be unified, in addition to a time constraint in which an OCV is acquired over about 10 minutes during charging and discharging in PTL 2.

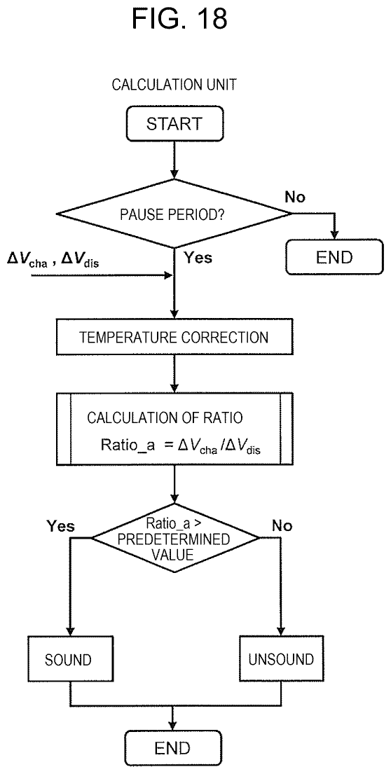

FIG. 18 is a flowchart showing an operation of a battery management device according to Embodiment 4. In Embodiment 4, before calculating the difference or ratio between ΔVdis and ΔVcha, a calculation unit applies the conversion equation to the difference or the ratio. However, when the current battery temperature is the same battery temperature as when a reference value used for performing determination of soundness is obtained, the conversion equation is not necessary. Other steps are the same as those in Embodiment 1.

### Embodiment 5

In Embodiment 5 of the invention, a method for evaluating soundness of a battery regardless of a current battery voltage by converting ΔVcha and ΔVdis into values corresponding to any battery voltage using a voltage correction equation will be described. Other configurations are the same as those in Embodiment 1.

In the deterioration detection using the OCV in PTL 2, ΔVcha and ΔVdis need to be measured at the same voltage. That is, in order to evaluate the soundness of the battery in PTL 2, it is necessary to measure ΔVcha and ΔVdis at a specific charge voltage and discharge voltage. Therefore, in Embodiment 5, ΔVcha and ΔVdis are acquired without adjusting a measurement voltage on a battery cell (or a battery module) side, and values thereof are converted into values corresponding to any battery voltage (charge voltage and discharge voltage) by a correction function. Accordingly, the soundness of the battery can be evaluated at any battery voltage without depending on a specific battery voltage.

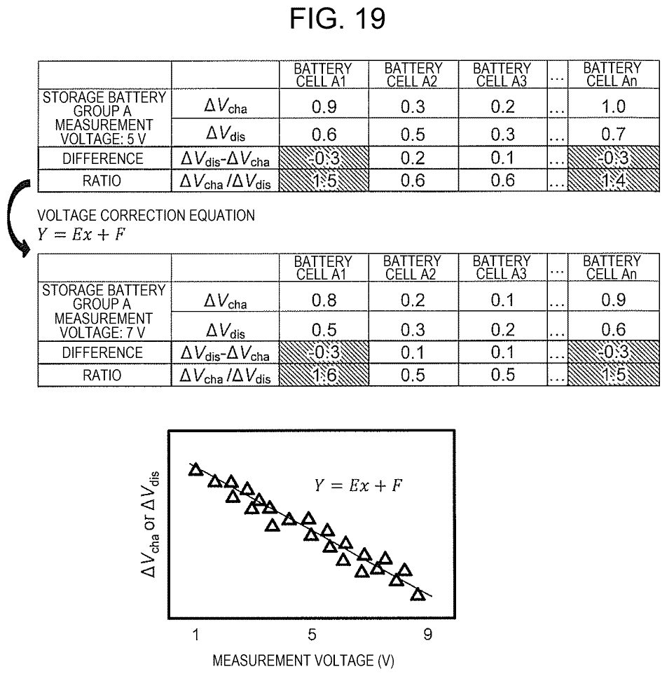

FIG. 19 is an example of data showing a calculation result when the voltage correction equation is applied to ΔVdis and ΔVcha. The upper part of FIG. 19 shows measurement results of ΔVdis and ΔVcha after charging and discharging at any battery voltage (in the upper part of

FIG. 19, both the charge voltage and the discharge voltage are 5 V). The middle part of FIG. 19 shows a result of conversion into a value corresponding to a battery voltage of 7 V by applying a voltage correction equation (Y=Ex+F (Equation 3)) to the battery voltage of 5 V in the upper part of FIG. 19.

The lower part of FIG. 19 shows a method for determining a conversion equation. ΔVdis and ΔVcha are acquired under various battery voltages, and a conversion equation is obtained by specifying an equation that approximates a relational equation therebetween.

When the upper part and the middle part of FIG. 19 are compared with each other, it can be seen that a battery having a deterioration state or a sign of a failure can be determined even when voltage correction is applied to ΔVdis and ΔVcha. In addition, a normal battery can be correctly determined. Accordingly, even when ΔVdis and ΔVcha are acquired under different battery voltages, it can be said that deterioration can be detected and a state of a battery having a possibility of a potential failure can be determined.

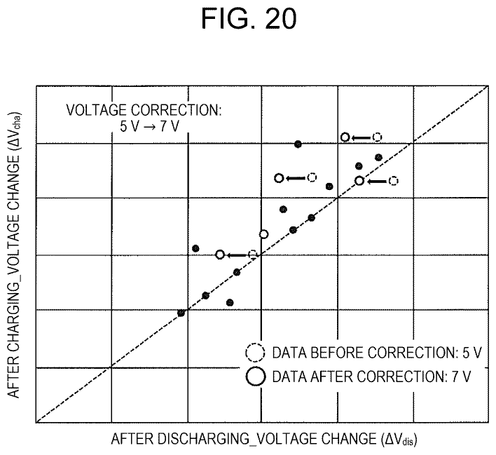

FIG. 20 shows a change in ΔVdis and ΔVcha plots when a battery voltage is corrected. A dotted line plot in FIG. 20 indicates data before correction (battery voltage: 5 V), and a solid line plot indicates data after correction (battery voltage: 7 V). The horizontal axis and the vertical axis are the same as those in Embodiment 3 and Embodiment 4. The data after correction can be applied to any of a sound battery, a battery in a deterioration state, and a battery having a sign of a failure. In addition, the determination of the battery having the sign of the failure in the plot after the correction is the same as that before the correction. By acquiring at least one of a difference and a ratio, it is possible to accurately detect a battery having a deterioration state or a sign of a failure.

In Embodiment 5, a degree of freedom of a measurement environment (charge voltage and discharge voltage) is added in addition to instantaneous measurement of ΔVdis and ΔVcha. This solves a problem of an environmental constraint (voltage) in which the charge voltage and the discharge voltage are to be unified, in addition to a time constraint in which an OCV is acquired over about 10 minutes during charging and discharging in PTL 2.

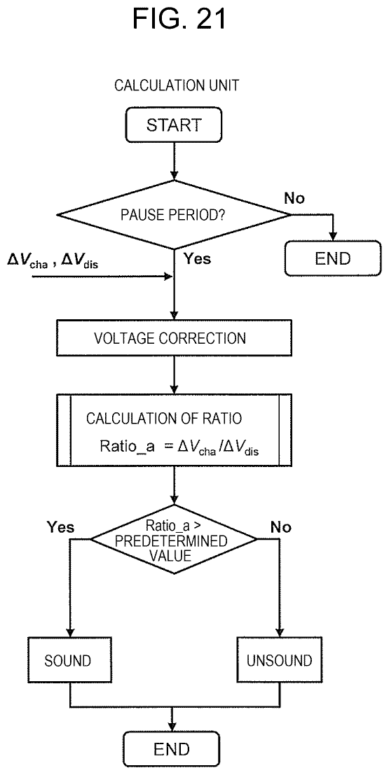

FIG. 21 is a flowchart showing an operation of a battery management device according to Embodiment 5. In Embodiment 5, before calculating the difference or ratio between ΔVdis and ΔVcha, a calculation unit applies the conversion equation to the difference or the ratio. However, when the current battery voltage is the same battery voltage as when a reference value used for performing determination of soundness is obtained, the conversion equation is not necessary. Other steps are the same as those in Embodiment 1.

### Embodiment 6

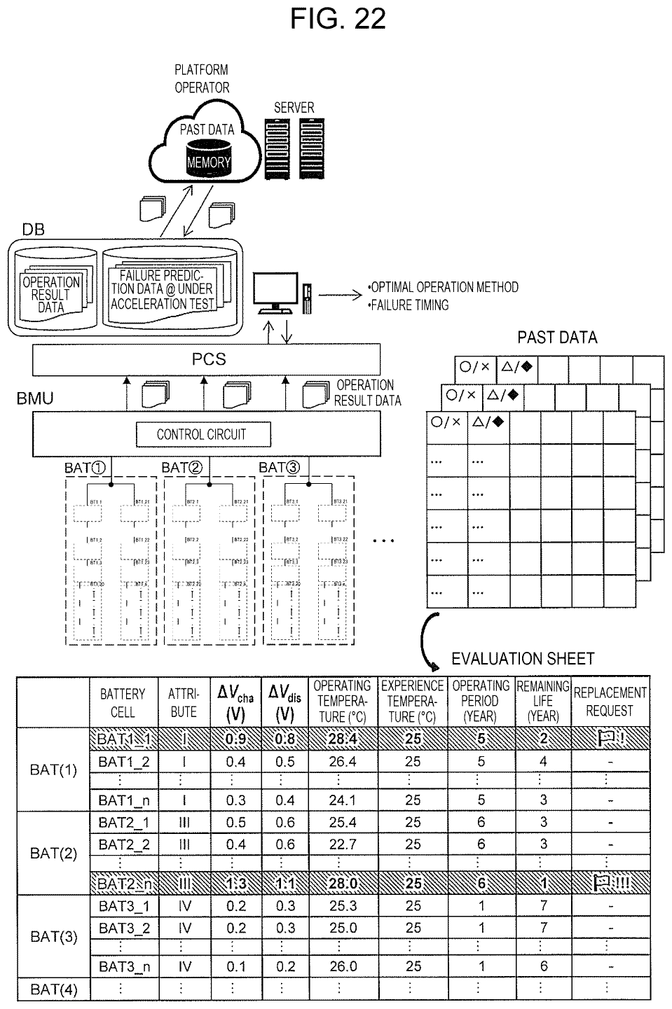

FIG. 22 is a schematic diagram showing an operation form of a battery management device according to Embodiment 6 of the invention. In Embodiment 6, the deterioration detection methods described in Embodiment 1 to Embodiment 5 and the information obtained from the operation result data are combined for a battery system operated over a long period such as a large-scale battery system for a system power supply, and the presence or absence of a deterioration state or a sign of a failure of a battery is detected.

The battery system shown in FIG. 22 transmits operation result data (including delivery data) of a battery group to a computer (calculation unit). Further, the operation result data stored in a database (DB) is transmitted to a server computer. The server computer is, for example, a computer provided by a platform operator operating the battery system. The server computer uses measurement data (battery voltage, battery current, and battery temperature) of the battery group and the operation result data to detect a deterioration state or a sign of a failure of the battery or to predict future deterioration. The computer that receives the measurement data from the battery system and the server computer provided by the operator may be integrated (that is, the computers may be used as a “calculation unit”).

In a case of a battery system that operates a plurality of battery cells, operation result data is stored for each battery cell. The operation result data includes at least one of an attribute, a voltage, a current, an operating temperature, an experience temperature, a remaining life, an operation period, and the number of operations. The computer (battery management device) extracts necessary information from the result data and creates a new evaluation sheet. In the battery system operated for a long period of time, in addition to ΔVdis and ΔVcha, an operating temperature and an operating time (or an operating period) during operation are important indicators. The indicators may be acquired from past operation result data.

The evaluation sheet created by the computer includes at least one of ΔVdis, ΔVcha, an operating temperature, an operating period, and a replacement request. The computer calculates a difference (ΔVdis−ΔVcha) or a ratio (ΔVcha/ΔVdis) from ΔVdis and ΔVcha of the evaluation sheet by the method in Embodiment 1. For battery cells displayed by shading of the evaluation sheet, an example in which ΔVdis and ΔVcha deviate and a replacement request warning is given is shown. From the calculation result, a deterioration state of a battery cell is determined, and a state of a battery having a possibility of a potential failure is determined. In addition to Embodiment 1, a threshold may be set based on a result of acceleration test data, and a battery having aged deterioration or a sign of a potential failure may be detected using at least one of operation result data in a market and training data using AI. By notifying a user of the result as a warning, it is possible to make a request to replace the battery half a year or more ago. In Embodiment 6, further, it is possible to detect a deterioration state including a past operating temperature or an operating time (or operating period) or a sign of a failure of a battery. Accordingly, since the deterioration transition described in Embodiment 1 can be grasped, it is possible to detect deterioration with high accuracy and predict an early failure of a battery. After the failure of the battery is detected, the battery cells or the battery group can be replaced in advance by displaying three stages of warnings from a failure detection result as shown in the GUI of FIG. 9B. A reference equivalent to the reference displayed on the GUI may be displayed on the evaluation sheet of Embodiment 6.

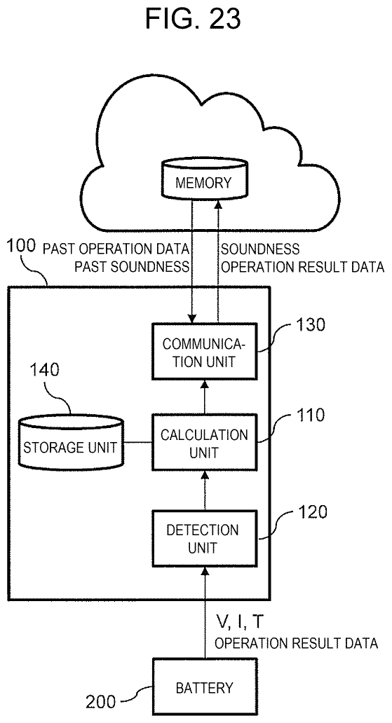

FIG. 23 is a diagram showing a configuration example of the battery management device according to Embodiment 6. Depending on a place where an algorithm for estimating soundness of the battery is performed, the evaluation of the soundness may be calculated, for example, on the device described above, or may be calculated on a computer connected via a network such as a cloud server. An advantage of calculation on the device to which the battery is connected is that a battery state (a voltage output by the battery, a current output by the battery, a temperature of the battery, and the like) can be acquired with high frequency.

The soundness evaluation calculated on a cloud system may be transmitted to the computer possessed by the user. The user computer can provide the data to a specific application such as inventory management. The soundness evaluation calculated on the cloud system can be stored in a database of a cloud platform operator and used for another application. In addition, since the past operation result data is stored in a memory in the cloud, the past operation result data may be transmitted to the computer possessed by the user, and may be used to determine aged deterioration.

In FIG. 23, a battery management device 100 is a device that acquires output data and operation result data from a battery 200 and evaluates soundness of the battery 200 using the output data and the operation result data. The battery management device 100 includes a communication unit 130, a calculation unit 110, a detection unit 120, and a storage unit 140.

The detection unit 120 acquires a voltage V output by the battery 200, an output current I of the battery, and a battery temperature T. Further, operation result data may be acquired. The detection values may be detected by the battery itself and notified to the detection unit, or may be detected by the detection unit.

The calculation unit 110 evaluates the soundness of the battery 200 using the detection values acquired by the detection unit 120. An estimation procedure has been described in Embodiment 1 to Embodiment 5. The communication unit 130 transmits the soundness evaluation and the operation result data output by the calculation unit 110 to the outside of the battery management device 100. For example, the soundness evaluation and the operation result data can be transmitted to the memory provided in the cloud system. The storage unit 140 can store measurement results (two-dimensional plots) of ΔVcha and ΔVdis, the reference value according to the battery type described in Embodiment 2, the conversion equations described in Embodiment 3 to Embodiment 5, and the like.

### Embodiment 7

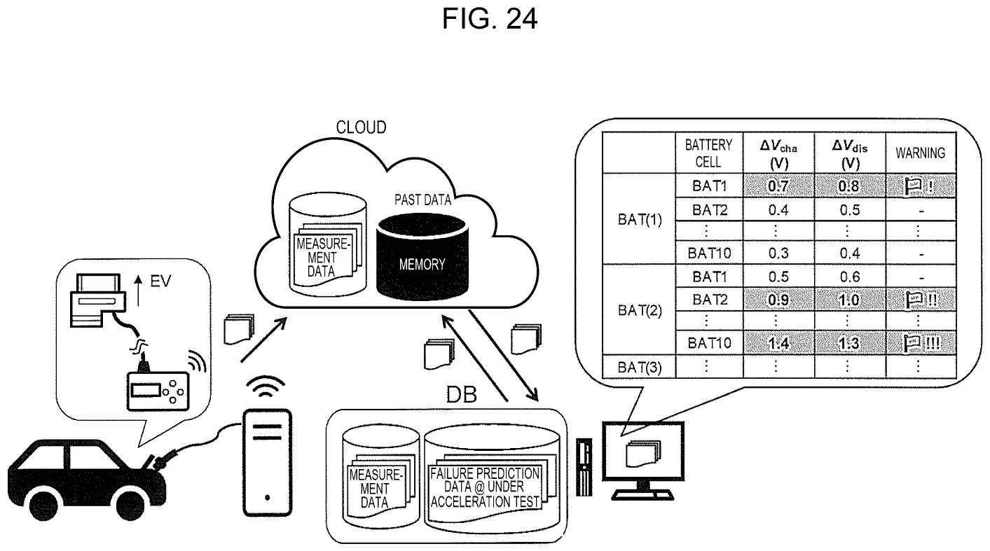

FIG. 24 shows an operation form of a battery management device according to Embodiment 7 of the invention. In Embodiment 7, a method for detecting the presence or absence of a deterioration state or a sign of a failure of a battery using measurement data obtained from an in-vehicle device or a charging port for an electric vehicle including an in-vehicle battery group will be described. The detection method is the same as in the above embodiments. By connecting the in-vehicle device or the charging port to the electric vehicle, measurement data (battery voltage, battery current, battery temperature, and the like) of the in-vehicle battery group can be acquired at any timing. The measurement data can be directly acquired from the in-vehicle device at any timing via predetermined communication. In the case of the charging port, the power supply device to which the control signal is transmitted is connected to the charging port, and a command is given, whereby the measurement data can be acquired from a BMU via the predetermined communication. The acquired measurement data may be stored on a cloud dedicated to a measuring instrument.

The embodiment further includes a function of storing data in a cloud on a server from the cloud dedicated to the measuring instrument via communication. When evaluation of a deterioration state or a battery state having a possibility of a failure is performed, measurement data from the past to the present is stored in a DB of the battery management device from the cloud on the server or the cloud dedicated to the measuring instrument.

This can also be implemented by an on-premise. Specifically, by providing a data storage in advance in the power supply device connected to the in-vehicle device or the charging port, ΔVcha and ΔVdis can be calculated instantaneously after acquiring the measurement data of the battery, and deterioration can be detected from a difference and a ratio. The embodiment can be applied to any in-vehicle device or power supply device as long as ΔVcha and ΔVdis can be acquired.

The difference (ΔVdis−ΔVcha) or the ratio (ΔVcha/ΔVdis) is calculated by the method of Embodiment 1 based on ΔVdis and ΔVcha of the battery acquired by the above method. From the calculation result, the deterioration state of the battery cell or the battery state having a possibility of a potential failure is determined. Since past data can also be used in the embodiment, it is possible to detect deterioration of a battery over time and predict a failure by acquiring ΔVdis and ΔVcha during periodic vehicle inspection such as vehicle inspection and storing ΔVdis and ΔVcha as the past data.

In response to a replacement request after failure detection, the battery cell or the battery group can be replaced in advance by displaying three stages of warnings from the failure detection result as shown in FIG. 9B. The same reference as the reference displayed on the GUI can be displayed on the battery management device in the embodiment.

An output value of the battery acquired on the cloud system may be transmitted to a computer possessed by a user. The user computer can provide the data to a specific application such as inventory management. The battery data acquired on the cloud system can be stored in a database of a cloud platform operator and used for another application. Output data of an in-vehicle storage battery acquired in the past is stored in a memory in the DB or the cloud, so that the output data from the battery can be transmitted to the computer possessed by the user and used for soundness evaluation. Accordingly, in addition to the on-site deterioration detection, the battery system can be managed only by exchanging data.

### Regarding Modification of Invention

The invention is not limited to the above-described embodiments and includes various modifications. For example, the above-described embodiments have been described in detail to facilitate understanding of the invention, and the invention is not necessarily limited to those including all the configurations described above. In addition, a part of a configuration according to a certain embodiment can be replaced with a configuration according to another embodiment, and a configuration according to another embodiment can be added to a configuration according to a certain embodiment. In addition, another configuration can be added to, deleted from, or replaced with a part of a configuration of each embodiment.

In the above embodiments, a battery system including battery cells (secondary batteries) connected in series or in parallel has been described as an example. As the battery, for example, lithium ion battery (LiB), another solid battery, a sodium battery, and the like can be used. In any of the batteries, a method of the invention can be applied using ΔVdis and ΔVcha.

Although the examples of converting the SoC, the battery temperature, and the battery voltage have been described in Embodiment 3 to Embodiment 5, one or more of these may be combined. For example, ΔVdis and ΔVcha may be converted into values corresponding to a specific SoC and a specific battery temperature. In this case, a conversion equation may be acquired in advance by acquiring ΔVdis and ΔVcha in various combinations of an SoC and a battery temperature.

In the above embodiments, the battery being sound means that performance deterioration of the battery after shipment is within a reference range (can be normally used). The battery is not sound means that the performance deterioration of the battery after shipment exceeds the reference range. Examples of a cause of the performance deterioration include aged deterioration, a failure, and composite factors thereof. Soundness and a degree of deterioration (or a degree of failure) of the battery can be defined by relative evaluation with respect to the performance at the time of shipping. For example, when the soundness is 100%, it is possible to evaluate that the product is new, and when the degree of deterioration is 10%, it is possible to evaluate that the performance is reduced by 10% from the new product.

In the above embodiments, a calculation unit that performs a deterioration detection procedure of a battery can be implemented by hardware such as a circuit device where a function of the calculation unit is provided, or can also be implemented by a calculation device such as a central processing unit (CPU) executing software where the function is provided.

### Reference Signs List

100: battery management device
110: calculation unit
120: detection unit
130: communication unit
140: storage unit
200: battery

1. A battery management device for managing a state of a battery, the battery management device comprising:
a detection unit configured to acquire a detection value of a voltage output from the battery; and
a calculation unit configured to estimate the state of the battery, wherein
the calculation unit specifies a first period from a completion time point at which charging of the battery is completed or from a start time point after the completion time point and before an inflection point of a curve of a change with time in the voltage to a first time point at which a first time has elapsed,
the calculation unit specifies a second period from the completion time point at which discharging of the battery is completed or from a start time point after the completion time point and before the inflection point of the curve of the change with time to a second time point at which a second time has elapsed,
the calculation unit acquires at least one of a difference between a first change amount of the voltage in the first period and a second change amount of the voltage in the second period, and a ratio between the first change amount and the second change amount, and
the calculation unit evaluates soundness of the battery based on at least one of the difference and the ratio, and outputs the result.

2. The battery management device according to claim 1, wherein
the calculation unit evaluates a degree of progress of aged deterioration of the battery according to a distance from an origin of a plot when the first change amount and the second change amount are plotted on a two-dimensional coordinate axis.

3. The battery management device according to claim 1, wherein
when the second change amount is equal to or larger than the first change amount, the calculation unit evaluates the soundness of the battery to be equal to or larger than a threshold.

4. The battery management device according to claim 2, wherein
the calculation unit determines that the battery, in which the first change amount is equal to or larger than the second change amount in the plot, is a battery having a sign of a failure, and
the calculation unit evaluates a period until the failure of the battery according to a distance from a reference value indicating that the battery is sound to the plot on the two-dimensional coordinate axis.

5. The battery management device according to claim 1, wherein
the calculation unit evaluates the soundness of the battery, in which at least one of the difference and the ratio is equal to or larger than a second threshold, as a failure occurring or a period until a failure occurs being less than a threshold.

6. The battery management device according to claim 1, wherein
the calculation unit sets, for each type of the battery, a linear function approximating a relationship between the first change amount and the second change amount, and
the calculation unit evaluates the soundness of the battery by comparing at least one of the difference and the ratio with the linear function.

7. The battery management device according to claim 6, wherein
the calculation unit sets at least one of a slope and an intercept of the linear function for each of the type of the battery, a characteristic of the battery, an attribute of the battery, or a combination of one or more of these,
the calculation unit sets at least one of the slope and the intercept for a first battery such that a range in which the battery is evaluated to be sound is a first normal range and a range in which the battery is evaluated to be deteriorated or failed is a first abnormal range,
the calculation unit sets at least one of the slope and the intercept for a second battery with a reference for being regarded as deteriorated is stricter than that of the first battery, such that a range in which the battery is evaluated to be deteriorated or failed is a second abnormal range narrower than the first abnormal range, and
the calculation unit sets at least one of the slope and the intercept for a third battery with a reference for being regarded as sound is gentler than that of the first battery, such that a range in which the battery is evaluated as sound is a second normal range wider than the first normal range.

8. The battery management device according to claim 1, wherein
the calculation unit estimates a period required until the soundness of the battery is less than a reference value, by predicting at least one of the difference and the ratio at a future time point based on a result of at least one of acceleration test data, operation result data in a market, and AI-based training data.

9. The battery management device according to claim 1, further comprising:
a user interface configured to present a processing result from the calculation unit, wherein
the user interface presents at least one of a change with time in the difference or the ratio during an operation period of the battery, the first change amount, the second change amount, and a result obtained by the calculation unit estimating the state of the battery.

10. The battery management device according to claim 1, wherein
the calculation unit acquires a correspondence relationship between the first change amount and the second change amount used to determine whether the battery is sound when the battery is in a first state of charge,
the calculation unit acquires the first change amount and the second change amount when the battery is in a second state of charge, and calculates a first post-conversion change amount and a second post-conversion change amount by converting values of the first change amount and the second change amount into corresponding values in the first state of charge, and
the calculation unit evaluates the soundness of the battery using the first post-conversion change amount, the second post-conversion change amount, and the correspondence relationship when the battery is in the second state of charge.

11. The battery management device according to claim 1, wherein
the calculation unit acquires a correspondence relationship between the first change amount and the second change amount used to determine whether the battery is sound when the battery is in a first temperature,
the calculation unit acquires the first change amount and the second change amount when the battery is in a second temperature, and calculates a first post-conversion change amount and a second post-conversion change amount by converting values of the first change amount and the second change amount into corresponding values in the first temperature, and
the calculation unit evaluates the soundness of the battery using the first post-conversion change amount, the second post-conversion change amount, and the correspondence relationship when the battery is in the second temperature.

12. The battery management device according to claim 1, wherein
the calculation unit acquires a correspondence relationship between the first change amount and the second change amount used to determine whether the battery is sound when a discharge voltage and a charge voltage of the battery are first voltage conditions,
the calculation unit acquires the first change amount and the second change amount when the discharge voltage and the charge voltage of the battery are second voltage conditions, and calculates a first post-conversion change amount and a second post-conversion change amount by converting values of the first change amount and the second change amount into corresponding values in the first voltage conditions, and
the calculation unit evaluates the soundness of the battery using the first post-conversion change amount, the second post-conversion change amount, and the correspondence relationship when the discharge voltage and the charge voltage of the battery are the second voltage conditions.

13. The battery management device according to claim 1, wherein
a plurality of the batteries are connected in series or in parallel to constitute a battery group,
the calculation unit monitors the battery group by acquiring an output voltage of each of the batteries, an output current of each of the batteries, a temperature of each of the batteries, an operating time or an operating period of each of the batteries, and a history of these, and
the calculation unit predicts a future failure of the battery group by comparing a result obtained by monitoring the battery group with a result of at least one of acceleration test data, operation result data in a market, and AI-based training data.

14. The battery management device according to claim 1, wherein
the calculation unit acquires an output voltage of the battery via a charging port of an electrical device in which the battery is mounted, and
the calculation unit acquires the first change amount and the second change amount using the output voltage acquired via the charging port.

15. A storage medium that stores a battery management program causing a computer to execute processing of managing a state of a battery, the battery management program causing the computer to execute:
a step of acquiring a detection value of a voltage output from the battery; and
a step of estimating the state of the battery, wherein
in the estimating step, the computer executes a step of specifying a first period from a completion time point at which charging of the battery is completed or from a start time point after the completion time point and before an inflection point of a curve of a change with time in the voltage to a first time point at which a first time has elapsed,
in the estimating step, the computer executes a step of specifying a second period from the completion time point at which discharging of the battery is completed or from a start time point after the completion time point and before the inflection point of the curve of the change with time to a second time point at which a second time has elapsed,
in the estimating step, the computer executes a step of acquiring at least one of a difference between a first change amount of the voltage in the first period and a second change amount of the voltage in the second period, and a ratio between the first change amount and the second change amount, and
in the estimating step, the computer executes a step of evaluating soundness of the battery based on at least one of the difference and the ratio, and outputting the result.
